(19) United States
(12) Patent Application Publication
(10) Pub. No.: US 2015/0048227 A1
(43) Pub. Date: Feb. 19, 2015

(54) RAIL BRACKET SECURING STRUCTURE

(71) Applicant: Ming-Hua Chuang, Changhua (TW)

(72) Inventor: Ming-Hua Chuang, Changhua (TW)

(73) Assignee: BIN YUANN FIRSTLINE INDUSTRIAL CORP., CHANGHUA (TW)

(21) Appl. No.: 13/970,541

(22) Filed: Aug. 19, 2013

(51) Int. Cl. F16B 9/02; H05K 5/02; F16B 2/22

(52) U.S. Cl. CPC F16B 9/023; F16B 2/22; H05K 5/0217
USPC 248/228.4

(57) ABSTRACT

A rail bracket securing structure may have a rail, a bracket, two controlling units, a resilient unit and a cover. In one embodiment, the controlling unit is pivotally secured on the bracket through a pin, and a handle portion of the controlling unit protrudingly extends in an evading slot, so the user can press the handle portion with one hand to uninstall the rail to not only increase the smoothness during operation, but also reduce the possibility of damaging the entire structure. Furthermore, one end of the rail is secured at the bracket and the controlling units are pivotally connected thereon, and the resilient unit is disposed between two controlling units, which reduces the costs of materials and achieves the goal of easy installation

### FIELD OF THE INVENTION

The present invention relates to a rail bracket securing structure, and more particularly to a rail securing structure used in server supporting units or devices.

### BACKGROUND OF THE INVENTION

A conventional rail securing structure is shown in FIG. 8. Both ends of the rail 70 has a connecting unit 80 to connect the rail 70 to the conjugating holes 91 of the supporting unit 90 to quickly assemble the rail 70 thereon. The connecting unit 80 has a shell 81, a fixed pin 82, a movable pin 83, a spring 84 and a button 85. The fixed pin 82 is located at the bottom portion of the shell 81, and one end of the fixed pin 82 is protrudingly outside the shell 81 has a pin portion 821, while the fixed pin 82 has a protruding stopping portion 822. The movable pin 83 is pivotally disposed at top portion of the shell 81 through a shaft stick 831, and one end of the movable pin 83 has a hook portion 832 protruding out from the shell 81, while the other end thereof has a connecting portion 833. Also, the movable pin 83 has a stopping surface 834 corresponding to the stopping portion 822 of the fixed pin 82 and the stopping surface 834 has a pressing surface 835 facing each other. One end of the spring 84 is fixed at the shell 81 an the other end is connected to the connecting portion 833 of the movable pin 83, so the movable pin 83 can move back and forth due to the resilient force. The button 85 is disposed on top of the shell 81 and the bottom of the button 85 is on the pressing surface 835 of the movable pin 83. When the rail 70 is uninstalled, the user presses the button 85 to push the pressing surface 835 of the movable pin 83, so the movable pin 83 can move around the shaft stick 831 to enable the hook portion 832 to detach from the conjugating hole 91 of the supporting unit 90.

### SUMMARY OF THE INVENTION

The technical problem the present invention wants to solve is that the pressing surface 835 of the movable pin 83 and the button 85 are contacted with each other with a plane and the button is disposed on the shell 81, so the button can only move vertically. When the button 85 is pressed, the movable pin 83 moves around the shaft stick 831 to create an angle between the pressing surface 835 and the button 85, which not only would create friction between the components, but also affect the smoothness of the operation. More importantly, because of the deflected force on button 85, the button 85 may be detached or jammed.

Secondly, the conjugation of the connecting unit 80 and the supporting unit 90 is through one end of the pin portion 821 of the fixed pin 82 and one end of the hook portion 832 of the movable pin 83 connecting with conjugating hole 91 of the supporting unit 90. The connecting unit 80 is positioned only by the fixed pin 82, and the movable pin 83 can serve the purpose of restriction. When the rail 70 is swinging or inclined at an angle, the movable pin 83 can be separated, so the rail 70 may be detached from the supporting unit 90.

Finally, the rail 70 and the supporting unit 90 are connected only by the fixed pin 82 and movable pin 83. When the rail 70 is heavily pressed or heavy objects are disposed thereon, the connecting unit 80 may be deformed because the structure is not strong enough. Therefore, there remains a need for a new and improved rail securing structure to overcome the problems presented above.

The present invention provides a rail bracket securing structure may include a rail, a bracket, two controlling units, a resilient unit and a cover. The bracket is formed as one piece having a fixed section and a connecting section, and the fixed section is connected with one end of the rail. One end of the connecting section close to the fixed section has a restricted portion, and two stopping portions are protrudingly and parallely formed at the other end of the connecting section. The stopping portion is bended and perpendicular to the connecting section to form an L-shaped shape to increase the structural strength thereof, and the hook of the controlling unit is restricted by the stopping portion. Also, a through hole is formed at an inner portion of each stopping portion. One end of each controlling unit has a hook and a handle portion is formed at the other end thereof. A connecting hole is formed between the hook and the handle portion, and a pin that can be secured at the through hole of the connecting section is used to insert into the connecting hole to secure to hooks at the stopping portion. The handle portion is disposed at both sides of the restricted portion and a front portion of the hook of the controlling unit has a guiding bevel. Furthermore, the controlling unit has a conjugating block at the handle portion. Center portion of the resilient unit is secured at the restricted portion of the bracket and the resilient unit extends from both ends to the handle portion of the controlling unit and the conjugating block is secured at outer portion of the resilient unit, so that the two hooks of the controlling units can be used to tightly clamp inward and the rail can be quickly detached by pressing the handle portion, wherein the connecting section of the bracket has an evading slot recessedly formed at both sides of the restricted portion, and the handle portion of the controlling unit is protrudingly formed at outer portion of the evading slot to enhance the pressing effect of the controlling unit. The cover covers the connecting section of the bracket to further restrict the controlling unit. The cover has two cover holes, so that the pin can pass through the cover holes to secure the cover and the bracket. Also, the cover has two evading gaps recessedly formed at the handle portion of the controlling unit, so the controlling unit can be more easily operated. Furthermore, the bracket has a stopping piece curvedly disposed corresponding to the handle portion of the controlling unit to restrict the opening of the handle portions. The cover has a screw hole corresponding to the stopping portion of the bracket with a corresponding bolt.

Comparing with the prior arts, the present invention is advantageous because (i) the controlling unit is pivotally secured on the bracket through the pin, and the handle portion of the controlling unit protrudingly extends in the evading slot, so the user can press the handle portion with one hand to uninstall the rail to not only increase the smoothness during operation, but also reduce the possibility of damaging the entire structure; (ii) one end of the rail is secured at the bracket and the controlling units are pivotally connected thereon, and the resilient unit is disposed between two controlling units, which reduces the costs of materials and achieves the goal of easy installation; (iii) two parallel L-shaped stopping portions are protrudingly formed at the connecting section of the bracket, and two stopping portions can be inserted into the conjugating holes of the supporting column to securely position the rail and increase the conjugating strength; and (iv) a screw hole is formed on the cover corresponding to the stopping portion of the bracket, and a bolt is provided for the conjugating hole of the supporting column and the screw hole of the cover to secure the rail and the supporting column to increase the conjugating strength.

### BRIEF DESCRIPTION OF THE DRAWINGS

FIG. 1 illustrates a three-dimensional view of the present invention.

FIG. 2 illustrates an exploded view of the structure in the present invention.

FIG. 3 illustrates a sectional view of the present invention.

FIG. 4 illustrates a sectional view of the pressing status in the present invention.

FIG. 5 illustrates a schematic view of the rail bracket securing structure in the present invention when it is in use.

FIG. 6 illustrates another schematic view of the rail bracket securing structure in the present invention when it is in use.

FIG. 7 illustrates a schematic view of the present invention connecting with supporting columns.

FIG. 8 is a prior art of the rail securing structure.

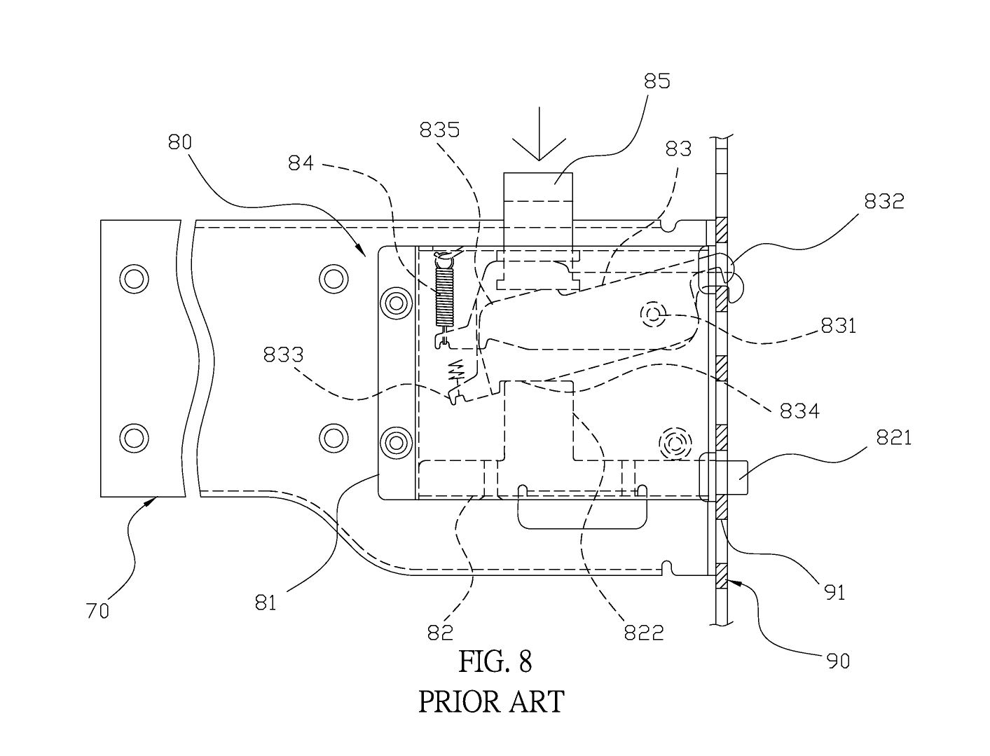

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

In order to further understand the goal, characteristics and effect of the present invention, a number of embodiments along with the drawings are illustrated as following:

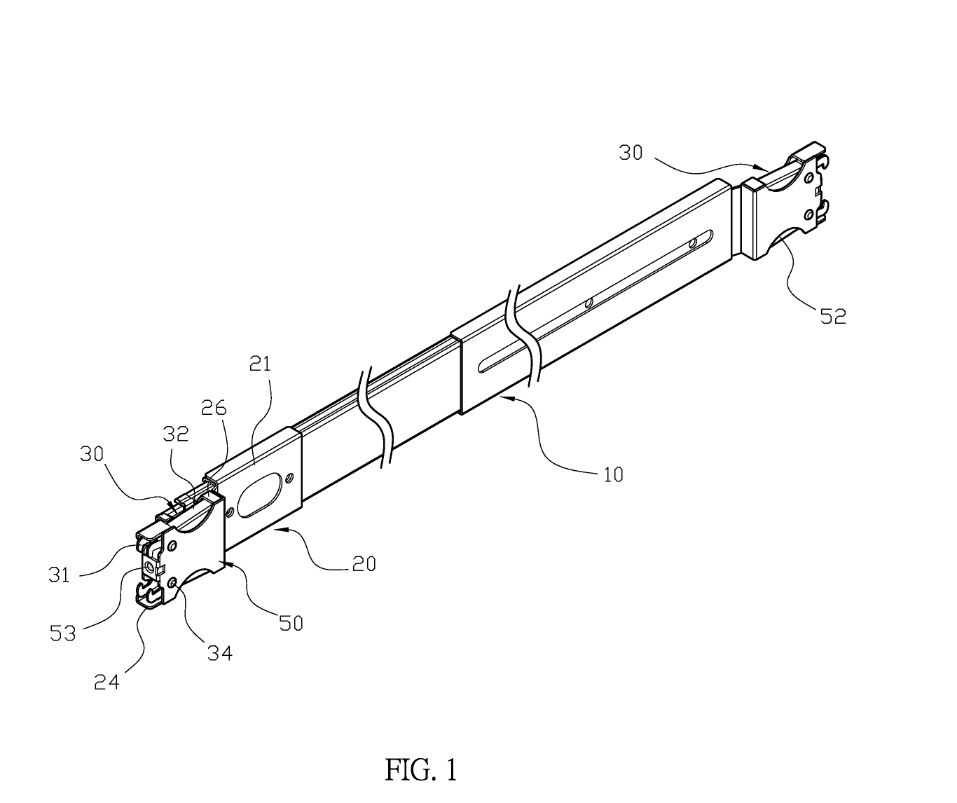

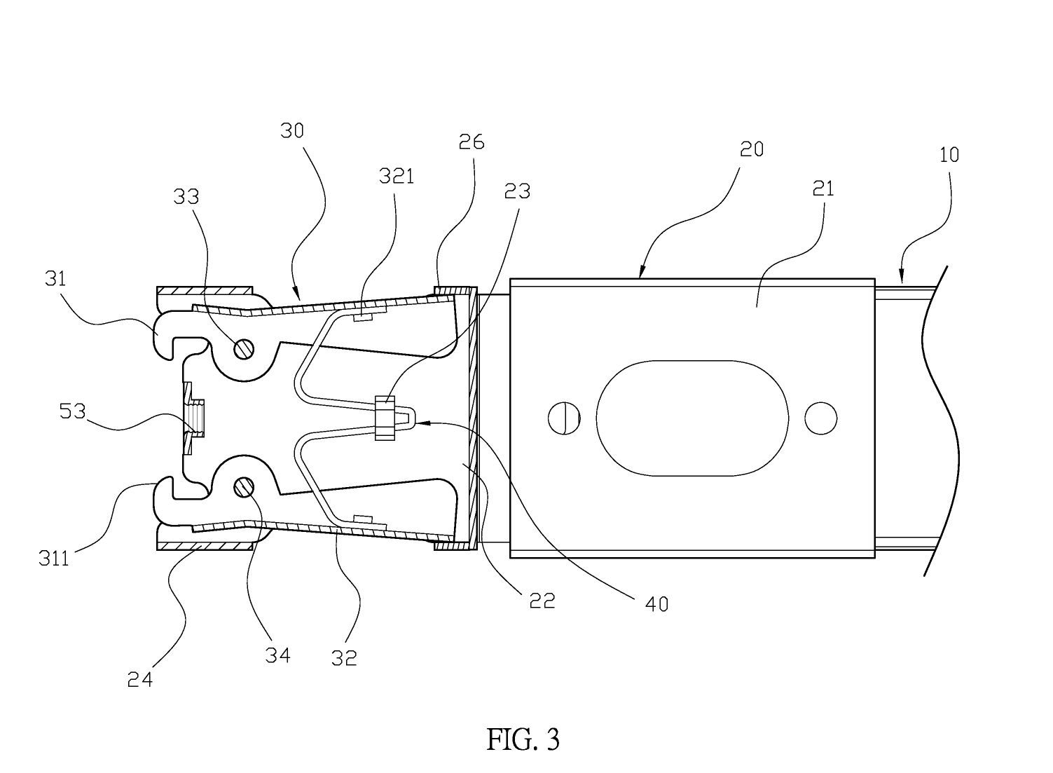

Referring to FIGS. 1, 2 and 3, a rail bracket securing structure may include a rail 10, a bracket 20, two controlling units 30, a resilient unit 40 and a cover 50. The bracket 20 is formed as one piece having a fixed section 21 and a connecting section 22, and the fixed section 21 is connected with one end of the rail 10. One end of the connecting section 22 close to the fixed section 21 has a restricted portion 23, and two stopping portions 24 are protrudingly and parallely formed at the other end of the connecting section 22. The stopping portion 24 is bended and perpendicular to the connecting section 22 to form an L-shaped shape to increase the structural strength thereof, and a hook 31 of the controlling unit 30 is restricted by the stopping portion 24. Also, a through hole 25 is formed at an inner portion of each stopping portion 24. One end of each controlling unit 30 has a hook 31 and a handle portion 32 is formed at the other end thereof. A connecting hole 33 is formed between the hook 31 and the handle portion 32, and a pin 34 that can be secured at the through hole 25 of the connecting section 22 is used to insert into the connecting hole 33 to secure to hooks 31 at the stopping portion 24. The handle portion 32 is disposed at both sides of the restricted portion 23 and a front portion of the hook 31 of the controlling unit 30 has a guiding bevel 311. Furthermore, the controlling unit 30 has a conjugating block 321 at the handle portion 32. Center portion of the resilient unit 40 is secured at the restricted portion 23 of the bracket 20 and the resilient unit 40 extends from both ends to the handle portion 32 of the controlling unit 30 and the conjugating block 321 is secured at outer portion of the resilient unit 40, so that the two hooks 31 of the controlling units 30 can be used to tightly clamp inward and the rail 10 can be quickly detached by pressing the handle portion 32, wherein the connecting section 22 of the bracket 20 has an evading slot 221 recessedly formed at both sides of the restricted portion 23, and the handle portion 32 of the controlling unit 30 is protrudingly formed at outer portion of the evading slot 221 to enhance the pressing effect of the controlling unit 30. The cover 50 covers the connecting section 22 of the bracket 20 to further restrict the controlling unit 30. The cover 50 has two cover holes 51, so that the pin 34 can pass through the cover holes 51 to secure the cover 50 and the bracket 20. Also, the cover 50 has two evading gaps 52 recessedly formed at the handle portion 32 of the controlling unit 30, so the controlling unit 30 can be more easily operated. Furthermore, the bracket 20 has a stopping piece 26 curvedly disposed corresponding to the handle portion 32 of the controlling unit 30 to restrict the opening of the handle portions 32. The cover 50 has a screw hole 53 corresponding to the stopping portion 24 of the bracket 20 with a corresponding bolt 54.

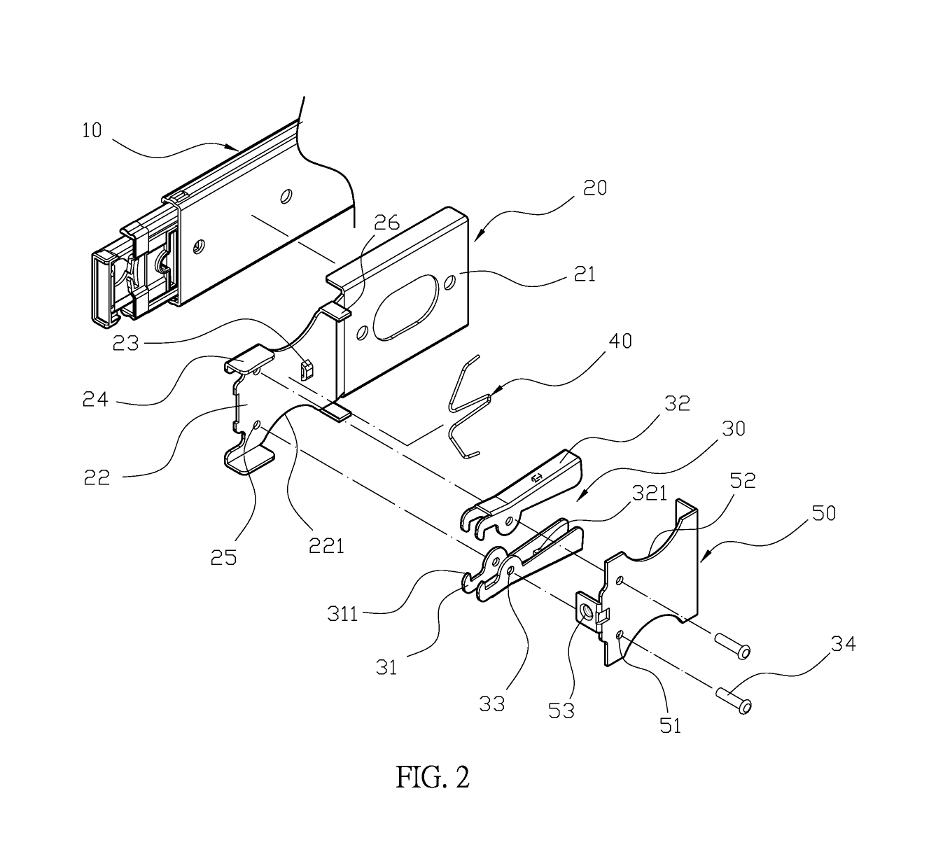

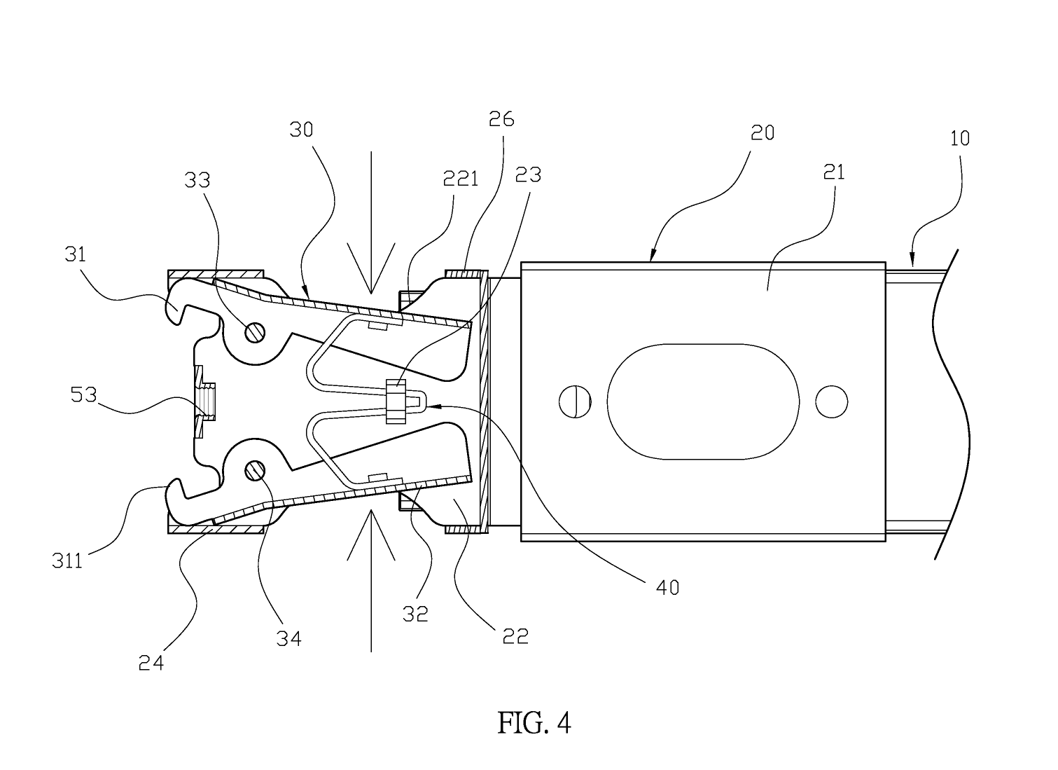

Referring to FIGS. 2 to 4 for the structure in the present invention, the bracket 20 is secured on the rail 10 through the fixed section 21 and the center portion of the resilient unit 40 is fixed to the restricted portion 23. The controlling unit 30 is disposed at the connecting section 22 of the bracket 20 and the handle portion 32 of the controlling unit 30 is disposed on both sides of the restricted portion 23, so that both sides of the resilient unit 40 engage with the handle portion 32 at the conjugating block 321. The connecting hole 33 of the controlling unit 30 is aligned with the through hole 25, so the hooks 31 of two controlling units 30 can be disposed on both sides of the stopping portion 24. The cover 50 is further connected with the connecting section 22 so the pin 34 can pass through the cover hole 51, connecting hole 33 and through hole 25 to secure the bracket 20 and the cover 50, and the controlling unit 30 can be disposed therebetween. When the user pushes the handle portion 32 of the controlling unit 30 with one hand, the controlling unit 30 is rotated around the connecting hole 33 to open up two hooks 31. When the user's hand releases, the resilient force generated by the resilient unit 40 pushes the handle portion 32 of the controlling unit 30, so that the hooks of the controlling units 30 come closer again to restore to the clamping status.

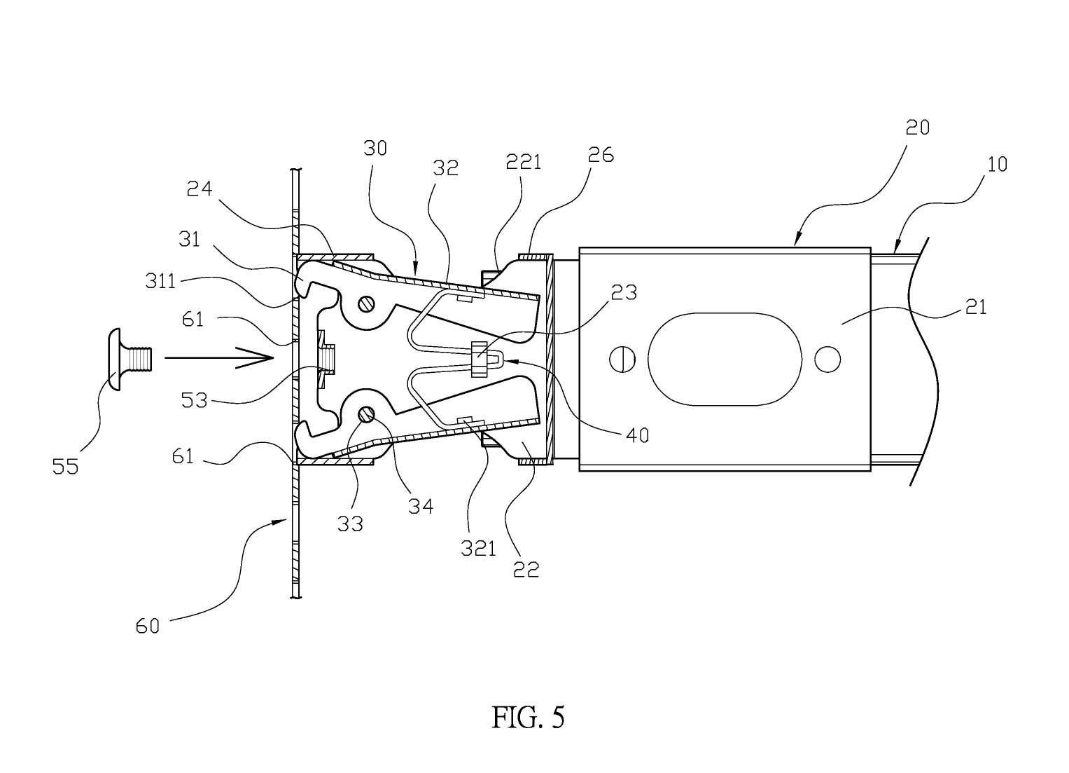

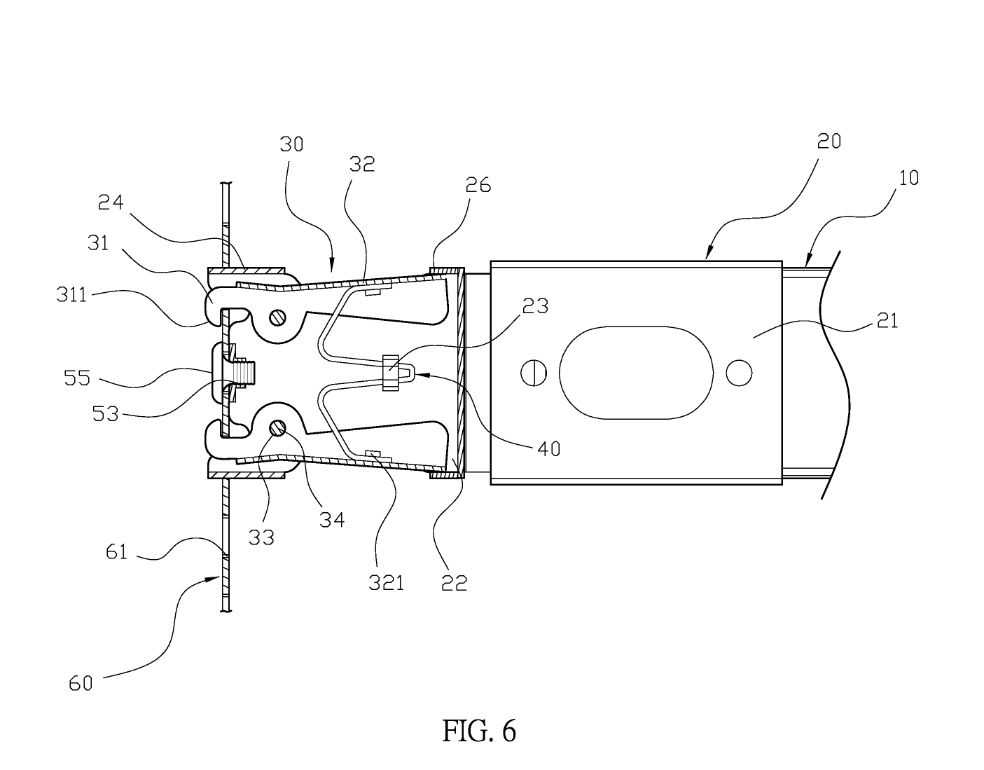

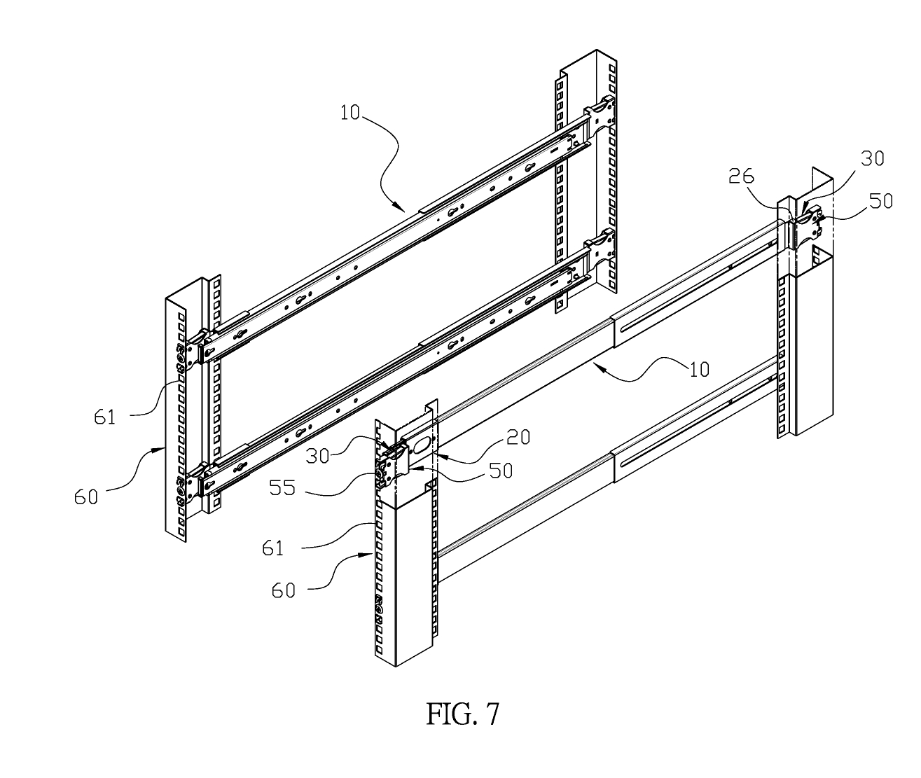

Referring to FIGS. 5 to 7 and FIG. 2, the rail 10 can be disposed inside a server or a server supporting unit to serve sliding purposes so the server can be conveniently move and disposed near computers or other electronic devices. Furthermore, a supporting column 60 is vertically disposed at four corners of the server supporting unit and a plurality of conjugating holes 61 are formed on the supporting columns 60. Since both sides of the rails 10 have brackets 20, controlling units 30 and resilient unit 40, when the rail 10 is installed, the stopping portion 24 of the bracket 20 passes through the conjugating hole 61 of the supporting column 60, and the hooks 31 of the controlling units 30 are disposed against the supporting column to automatically open up through the guiding bevel 311 to clamp the conjugating holes 61, so the stopping portion 24 of the bracket 20 can be secured at the conjugating holes 61. The user can also press on the handle portion 32 of the controlling unit 30 to dispose the hooks 31 outwardly to the stopping portion 24 of the bracket 20, so that the bracket 20 and the controlling units 30 can be completely inserted into the conjugating holes to quickly install the rail 10. When the rail 10 is uninstalled, the user can still press the handle portion 32 of the controlling unit 30 with one hand to pull the hooks 31 out of the conjugating holes 61 of the supporting column 60. In another embodiment, the bolt 54 is provided for the conjugating hole 61 of the supporting column 60 and the screw hole 53 of the cover 50 to secure the rail 10 and the supporting column 60 to increase the conjugating strength.

According to the embodiments described above, the present invention is advantageous because (i) the controlling unit 30 is pivotally secured on the bracket 20 through the pin 34, and the handle portion 32 of the controlling unit 30 protrudingly extends in the evading slot 221, so the user can press the handle portion 32 with one hand to uninstall the rail 10 to not only increase the smoothness during operation, but also reduce the possibility of damaging the entire structure; (ii) one end of the rail 10 is secured at the bracket 20 and the controlling units 30 are pivotally connected thereon, and the resilient unit 40 is disposed between two controlling units 30, which reduces the costs of materials and achieves the goal of easy installation; (iii) two parallel L-shaped stopping portions 24 are protrudingly formed at the connecting section 22 of the bracket 20, and two stopping portions 24 can be inserted into the conjugating holes 61 of the supporting column 60 to securely position the rail 10 and increase the conjugating strength; and (iv) a screw hole 53 is formed on the cover 50 corresponding to the stopping portion 24 of the bracket 20, and a bolt 54 is provided for the conjugating hole 61 of the supporting column 60 and the screw hole 53 of the cover 50 to secure the rail 10 and the supporting column 60 to increase the conjugating strength.

Having described the invention by the description and illustrations above, it should be understood that these are exemplary of the invention and are not to be considered as limiting. Accordingly, the invention is not to be considered as limited by the foregoing description, but includes any equivalents.

What is claimed is:

1. A rail bracket securing structure comprising:
a rail;
a bracket formed as one piece having a fixed section and a connecting section, wherein the fixed section is connected with one end of the rail, and one end of the connecting section close to the fixed section has a restricted portion, and two stopping portions are protrudingly and parallely formed at the other end of the connecting section, and a through hole is formed at an inner portion of each stopping portion.
two controlling units, one end of each controlling unit having a hook and a handle portion formed at the other end thereof, wherein a connecting hole is formed between the hook and the handle portion, and a pin that is secured at the through hole of the connecting section is used to insert into the connecting hole to secure to hooks at the stopping portion, and the handle portion is disposed at both sides of the restricted portion;
a resilient unit, center portion of the which secured at the restricted portion of the bracket, wherein the resilient unit extends from both ends to the handle portion of the controlling unit, so that the two hooks of the controlling units are able to tightly clamp inward and the rail is allowed to be quickly detached by pressing the handle portion.

2. The rail bracket securing structure of claim 1, wherein the stopping portion is bended and perpendicular to the connecting section to form an L-shaped shape to increase the structural strength thereof, and the hook of the controlling unit is restricted by the stopping portion.

3. The rail bracket securing structure of claim 1, wherein the connecting section of the bracket has an evading slot recessedly formed at both sides of the restricted portion, and the handle portion of the controlling unit is protrudingly formed at outer portion of the evading slot to enhance the pressing effect of the controlling unit.

4. The rail bracket securing structure of claim 1 further comprising a cover covering the connecting section of the bracket to further restrict the controlling unit, wherein the cover has two cover holes, so that the pin is allowed to pass through the cover holes to secure the cover and the bracket.

5. The rail bracket securing structure of claim 4, wherein the cover has two evading gaps recessedly formed at the handle portion of the controlling unit, so the controlling unit is allowed to be more easily operated.

6. The rail bracket securing structure of claim 4, wherein the cover has a screw hole corresponding to the stopping portion of the bracket with a corresponding bolt.

7. The rail bracket securing structure of claim 1, wherein a front portion of the hook of the controlling unit has a guiding bevel, and the controlling unit has a conjugating block at the handle portion to conjugate at outer portion of the resilient unit.

8. The rail bracket securing structure of claim 1, wherein the bracket has a stopping piece curvedly disposed corresponding to the handle portion of the controlling unit to restrict the opening of the handle portions.
